(19) United States
(12) Patent Application Publication
(10) Pub. No.: US 2009/0026564 A1
(43) Pub. Date: Jan. 29, 2009

(54) SEMICONDUCTOR COMPONENT, LIGHTING UNIT FOR MATRIX SCREENS, AND METHOD FOR MANUFACTURING A SEMICONDUCTOR COMPONENT

(76) Inventors: Achim KRUCK, Pfedelbach (DE); Hans-Peter Waible, Flein (DE)

Correspondence Address: Muncy, Geissler, Olds & Lowe, PLLC, P.O. BOX 1364, FAIRFAX, VA, 22038-1364, US

(21) Appl. No.: 12/179,742

(22) Filed: Jul. 25, 2008

Related U.S. Application Data
(60) Provisional application No. 60/951,946, filed on Jul. 25, 2007.

(30) Foreign Application Priority Data
Jul. 25, 2007 (DE) DE 102007034782.2

(51) Int. Cl. H01L 31/0232; H01L 21/31

(52) U.S. Cl. 257/432; 438/73; 257/E31.128; 257/E21.24

(57) ABSTRACT

A semiconductor component, lighting unit for matrix screens, and method for manufacturing a semiconductor component is provided. The semiconductor component includes an integrated circuit, which has at least one light detector provided with a silicon-containing coating, particularly a coating of silicon nitride or silicon dioxide. A layer thickness of the silicon-containing coating, particularly the coating of silicon nitride or silicon dioxide, is selected in such a way that a predefinable, narrow-band, wavelength-selective transmission of light waves, particularly of light waves in a wavelength range from 300 nm to 850 nm, can be achieved.

This nonprovisional application claims priority to German Patent Application No. DE 10 2007 034 782.2, which was filed in Germany on Jul. 25, 2007, and to U.S. Provisional Application No. 60/951,946, which was filed on Jul. 25, 2007, and which are both herein incorporated by reference.

### BACKGROUND OF THE INVENTION

1. Field of the Invention

The present invention relates to a semiconductor component with an integrated circuit, which has at least one light detector provided with a silicon-containing coating, particularly a coating of silicon nitride or silicon dioxide, as well as to lighting for matrix screens, and a method for manufacturing a semiconductor component.

2. Description of the Background Art

U.S. Pat. No. 4,131,488 discloses a light detector made as a photodiode, which is provided with an antireflective coating, to assure an advantageous efficiency between the light incident on the photodiode surface and the electric current that can be influenced by the photodiode. A high sensitivity of the photodiode for the incident light can be achieved in this way. The antireflective coating is realized as a layered structure of silicon dioxide and silicon nitride and enables broadband transmission of light waves of different wavelengths to the active surface of the photodiode, so that a high efficiency is assured virtually independent of the composition of the incident light.

Unexamined German Patent Application No. DE 40 19 853 C2, which corresponds to U.S. Pat. No. 5,736,773 discloses a semiconductor photodiode with an antireflective coating for use in optical measuring devices to measure optical power. In this case, the goal is to achieve an at least nearly constant spectral overall conversion factor, so that all incident light rays with different wavelengths substantially lead to an identical signal of the semiconductor photodiode.

### SUMMARY OF THE INVENTION

It is therefore an object of the invention is to provide a semiconductor component with a light detector, which is formed with a simple construction for detecting one or more narrow-band wavelength ranges.

This object is achieved by means of a semiconductor component of the aforementioned type, in which a layer thickness of the silicon-containing coating, particularly the coating of silicon nitride or silicon dioxide, is selected in such a way that a predefinable, narrow-band, wavelength-selective transmission of light waves, particularly of light waves in a wavelength range from 400 nm to 850 nm, can be achieved. The silicon-containing coating, preferably prepared from silicon nitride (Si₃N₄), is used in the manufacture of semiconductor components, particularly in CMOS processes, in a standard manner as a passivation layer and as an antireflective layer and has a refractive index of approximately n=1.95. Alternatively, silicon dioxide (SiO₂) can be used as the silicon-containing coating. The layer thickness of the coating determines the behavior of the light rays passing through the coating and amplified or attenuated depending on the selected layer thickness and wavelength by constructive or destructive interference. The light detector typically has a wavelength-dependent sensitivity determined physically by its internal structure. The coating can be matched with respect to its thickness in such a way that the light detector in one or more definable wavelength regions has a high efficiency between the incident light and the electric current influenced by the photodiode, whereas in other wavelength ranges there is a lower efficiency between light and current. A high efficiency in this case means that even with a minor change in the illumination intensity of the incident light, a correspondingly major change occurs in the current influenced by the photodiode, whereas at a low efficiency only a low change occurs in the influenced current. To this end, the layer thickness of the coating is selected in such a way that light with a desired wavelength in a narrow-band wavelength range can pass through the coating with a high transmission. Light with wavelengths outside this wavelength range is reflected partially or totally at the coating and therefore strikes the light detector with a reduced intensity and thereby has a rather small part or no part in influencing current flow through the light detector. Preferably, the coating has a transmission greater than 50% for a wavelength range with a bandwidth of 50 nm, preferably 30 nm, especially preferably 20 nm, and particularly 15 nm. However, light rays with wavelengths that lie nearby outside this wavelength band penetrate to the light detector through the coating with a transmission less than 50%. Thus, the desired narrow-band wavelength selectivity is achieved.

An embodiment of the invention provides that the silicon-containing coating is made as a homogeneous single-component layer, particularly with a layer thickness in the range between 50 nm and 4000 nm, preferably with a layer thickness that corresponds to an integer multiple of a fourth of the wavelength of the light waves to be transmitted. Thereby, a simple and cost-effective structure of a semiconductor component can be realized, because apart from the passivation of the semiconductor component, the conditions necessary for the narrow-band, wavelength-selective light detection of the light detector can also be created with the silicon-containing coating. The coating is applied to the integrated circuit as a single layer or as a multiple layer sequence in each case of similar material layers, whereby only property gradients, caused by production technology, occur between the layers, but the coating overall is to be regarded as homogeneous. It is provided according to the invention that all layers of the coating are chemically at least virtually identical and at least substantially free of predetermined property gradients. Preferably, a layer thickness t [m] of the silicon-containing coating is provided, which corresponds to an integer multiple n [−] of a fourth of the wavelength λ [m] of the light waves to be transmitted, so that the layer thickness of the coating is selected according to the following equation:

t=n*λ/4[m],

to enable the highest possible transmission of light waves with the wavelength λ to the light detector, whereas light waves with different wavelengths strike the light detector at a lower transmission and are mainly reflected by the coating.

Another embodiment of the invention provides that the layer thickness of the silicon-containing coating is selected in such a way that an inhomogeneous reception characteristic of the light detector is compensated at least partially for different light wavelengths. A light detector usually has a wavelength-dependent sensitivity. It is typical that the light detector has the sensitivity maximum at a certain wavelength. By way of example, a light detector configured as a CMOS detector, bipolar detector, PN diode, or PIN diode is especially sensitive for a light wavelength of 658 nm. In other words, this wavelength produces the greatest current flow in the light detector at an irradiance that is the same for all wavelengths. Light with other wavelengths leads to a low current flow in the light detector. To achieve an at least virtually identical sensitivity of the light detector for the light wavelength of 658 nm and for a second light wavelength, the layer thickness of the silicon-containing coating is selected in such a way that transmission is especially high for the second light wavelength and accordingly lower for the light wavelength of 658 nm. It is achieved as a result that light with the second wavelength causes the same current flow through the light detector as light with a wavelength of 658 nm. The layer thickness of the silicon-containing coating is therefore selected in an advantageous manner in such a way that a high sensitivity of the light detector for a first wavelength (by means of low coating transmission for the first wavelength) is adjusted to a low sensitivity of the light detector for a second wavelength (at high coating transmission for the second wavelength) and, therefore, an at least partial compensation of the sensitivity of the light detector can be achieved.

This is especially interesting for use of the semiconductor component as a sensor for light rays reflected at optical storage media for reading stored information. For this purpose, scanning of the storage medium with two light sources that have different wavelengths is increasingly provided. In this case, the light detector ideally has an at least similar, preferably identical efficiency, achieved by the adjusted coating, for both light wavelengths.

It is provided in another embodiment of the invention that at least two light detectors, which have coatings with a different layer thickness for detecting different light wavelengths, are provided in the integrated circuit. By means of the different coating layer thicknesses on the preferably otherwise technically identically designed light detectors, these detectors can be optimized for receiving different light wavelengths.

Another embodiment of the invention provides that the integrated circuit is set up for detecting an emission spectrum of a light source arrangement made of several light sources, particularly light-emitting diodes, and emits light in different wavelength ranges. By selective control of the light sources, the light source arrangement can radiate light that includes components with a different spectral wavelength distribution and a different intensity. In this way, the hue of the light emitted by the light source arrangement can be adjusted. The light detectors in this case are used for analyzing the light transmitted by the light source arrangement, whereby each light detector is matched to a wavelength emitted by the light source arrangement. For this purpose, the thickness of the coating on the light detector is selected in each case so that high transmission for the light wavelength to be detected or for the narrow-band wavelength spectrum of the respective light source is assured. The light wavelengths of the other light sources, which can emit light in different spectral wavelength ranges, are at least substantially blocked by the respective coating and do not influence the respective light detector.

Another embodiment of the invention provides that a control unit for processing light detector signals is provided. This makes possible an immediate evaluation of the signals generated by the light detectors to the semiconductor component, without the signals having to be amplified in a costly manner and having to be transmitted to a downstream, discretely configured electronic circuit.

Another embodiment of the invention provides that the control unit is formed to control light sources, particularly depending on signals of the light detectors. As a result, the amount of light emitted by the light sources and the light composition can be controlled to assure, for example, true-color lighting at the lowest possible energy consumption. This is of interest particularly in display devices for battery-operated devices, which are equipped with a plurality of light sources, particularly light-emitting diodes, and in which low current consumption is sought. Depending on a desired contrast and a desired brightness for the display device, the light sources can be supplied with electric energy over a broad interval, which can result in at least gradual differences in the specifically emitted wavelength spectrum. To assure that there is an advantageous color composition for the display unit at each point in time, the color composition of the display unit can be analyzed by scanning the light sources with the light detectors. When predefinable limit values for color deviations are exceeded, correction of the color composition can be achieved using the control unit by increasing or reducing the current supply to the affected light sources. Thus, for example, color deviations, arising due to temperature fluctuations or aging phenomena, in organic light-emitting diodes, fluorescent displays, or liquid crystal displays are compensated.

Another embodiment of the invention provides that the at least two light detectors have different layer thicknesses of the silicon-containing coatings, so that they have different sensitivities for incident light waves. The sensitivity of the particular light detector is determined by the layer thickness of the coating on the light detectors using transmission properties determined thereby. Thereby, for example, a first light detector has a high sensitivity for a first wavelength due to the thickness of its coating, whereas a second light detector has a low sensitivity for the same wavelength due to the thickness of its coating. On the contrary, the reverse sensitivity distribution occurs for a second wavelength. The thickness of the second coating results from the thickness of the first coating and a second coating applied selectively to the second light detector. In a plurality of light detectors with different thicknesses of the coatings, these can be applied in successive steps so that the thickest coating results as a sum of all coating thicknesses.

Another embodiment of the invention provides that the control unit for compensating signals of a light detector with broadband wavelength selection based on signals of the least one light detector is formed with narrow-band wavelength selection. Because the wavelength selectivity of the coating is not the same for each wavelength range, a first light detector whose coating is matched to a first wavelength, is set up for receiving light from a narrow-band wavelength spectrum. As an example, the first light detector is provided with a coating, which allows light transmission by more than 50% only for wavelengths in the range of 10 nm around a first principal wavelength. A second light detector whose coating is matched to another light wavelength, on the contrary, because of the characteristics of the coating provided for this receives light from a broader wavelength spectrum, in which a portion of light of wavelengths that are also received by the first light detector may also be contained. As an example, the second light detector is provided with a coating that allows light transmission of more than 50% for wavelengths in a range of 30 nm around a second principal wavelength. In this case, the first and the second principal wavelengths are spaced apart, for example, by a wavelength difference of 30 nm. It is provided according to the invention to subtract the light portion of the first wavelength range, as determined by the first light detector, from the total signal of the second light detector to obtain thereby a corrected signal of the second light detector, which thereby allows improved information about the light intensity in a second, more narrow-band wavelength range.

According to another aspect of the invention, a lighting unit is provided for screens, particularly for matrix screens, having at least one semiconductor component according to any one of claims 1 through 13. Lighting or backlighting of the matrix screen, which may be made, for example, as a thin-film transistor monitor (TFT monitor), can be checked and optionally adjusted, preferably regulated, with the semiconductor component of the invention.

According to another aspect of the invention, a method for manufacturing an integrated circuit with the following steps is provided: application of a silicon-containing coating, particularly a silicon nitride layer or a silicon dioxide layer, with a first layer thickness to a group of light detectors, selective application of a silicon-containing coating, particularly a silicon nitride layer or a silicon dioxide layer, with a second layer thickness to a subgroup of the group of light detectors. The method can be performed with known photolithographic patterning methods and leads to a homogeneous single-component layer with a locally adjusted different layer thickness. It is provided in this case that the silicon-containing coating, particularly the silicon nitride layer, is applied by a PECVD process step (plasma-enhanced-chemical-vapor-deposition process step) after passivation of the surface of the integrated circuit and opening of optical windows above the light detectors. It can also be provided to apply additional silicon-containing coatings, particularly layers of silicon nitride or a silicon dioxide layer, with the same or different layer thicknesses.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic top view of a semiconductor element with a group of light detectors and a light-emitting diode arrangement,

FIG. 2 shows a sectional view of the semiconductor component according to FIG. 1,

FIG. 3 shows a schematic sectional view of an arrangement of the semiconductor component according to FIGS. 1 and 2 on a light-emitting diode arrangement,

FIG. 4 shows a schematic plot of progression curves of a light detector potential versus layer thickness of a silicon nitride coating for two light wavelengths, and

FIG. 5 shows a schematic plot of progression curves of a light detector potential versus the light wavelength for different layer thickness of a silicon nitride coating.

### DETAILED DESCRIPTION

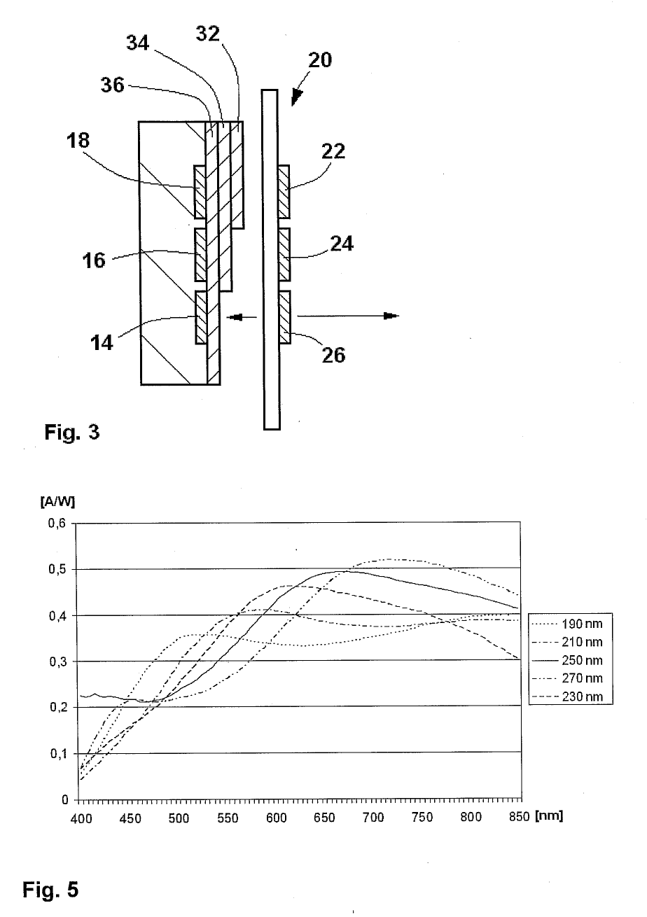

A semiconductor component 10, which is configured as a multichip module (MCM) and is shown schematically but not to scale in FIG. 1, has an integrated circuit formed on a silicon substrate 12 using Bi-CMOS technology (complementary metal-oxide semiconductor technology) of several layers, which are not shown in greater detail. The integrated circuit has several light detectors made as photodiodes 14, 16, 18, which in the exemplary embodiment according to FIG. 3 are each assigned to one of three light-emitting diodes 22, 24, and 26 of a light-emitting diode arrangement 20. Furthermore, a series of bond pads 28 is provided for electric coupling of the integrated circuit to electronic circuitry, not shown in greater detail.

Photodiodes 14, 16, and 18 are connected to a control unit, which is not shown in greater detail and is also part of the integrated circuit and which enables evaluation of electrical signal levels, produced by photodiode 14, 16, 18 upon incidence of light. The control circuit is also connected electrically to light-emitting diodes 22, 24, 26 and is provided for selective control of light-emitting diodes 22, 24, 26, each of which is provided for sending out light waves with different wavelengths.

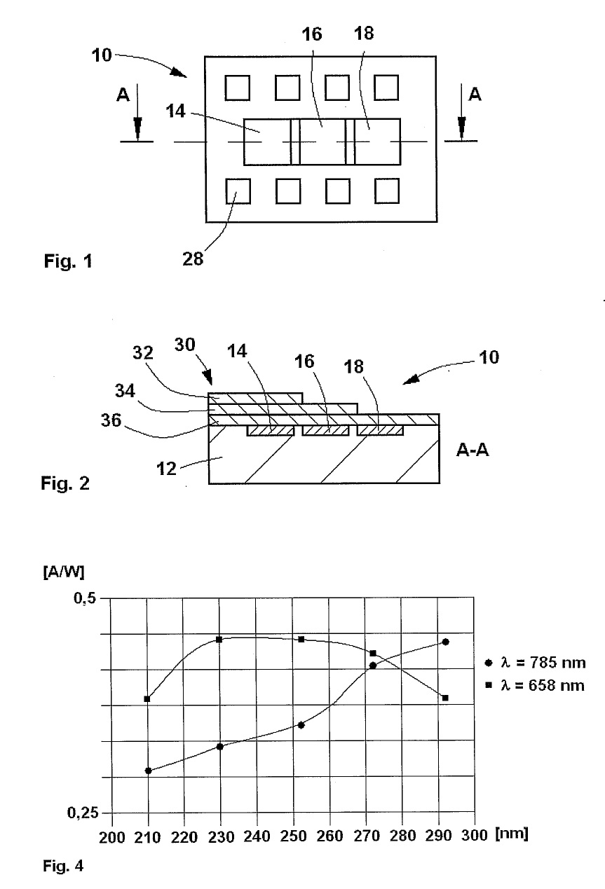

A layered structure of a silicon nitride layer 30 applied to the integrated circuit is shown in greater detail in the schematic sectional view, which is not to scale, in FIG. 2. Silicon nitride layer 30 is made of three single layers 32, 34, and 36. The shown layer thickness of single layers 32, 34, 36 is only schematic and not to be regarded as limiting. A window-like recess is provided in the top single layer 32 in the area above photodiodes 16 and 18, so that photodiode 16 is assigned only two single layers 34, 36 of the silicon nitride layer. A recess is provided in the area above photodiode 18 in the middle of single layer 34, so that photodiode 18 is assigned only one single layer 36.

The layer thickness of the single layers 32, 34, and 36 is selected in such a way that the bottom single layer 36 has a maximum transmission for a narrow-band, first wavelength range, whereas the middle single layer 34 together with the bottom single layer 36 has a maximum transmission for a narrow-band, second wavelength range that is spaced from the first wavelength range. In other words, the first wavelength range has a wavelength interval that is different from the wavelength interval of the second wavelength range in such a way that the second wavelength interval is not contained or contained only to a small extent in the first wavelength interval.

The combination of all three single layers 32, 34, and 36 has a maximum transmission for a narrow-band, third wavelength range, which is spaced from the first and second wavelength range. Therefore, photodiode 18 has a maximum sensitivity for the first wavelength range, whereas photodiode 16 has a maximum sensitivity for the second wavelength range. Photodiode 14 has a maximum sensitivity for the third wavelength range.

Thus, detection of a color composition resulting from the emitting behavior of light-emitting diodes 22, 24, 26, shown in greater detail in FIG. 3, can be undertaken with use of photodiodes 14, 16, 18, whose particular signal level is evaluated by the control unit. It is provided by way of example that light-emitting diodes 22, 24, and 26 according to the drawing of FIG. 3 have a main emission direction directed to the right, whereas only a fraction of the optical power is emitted in the direction of photodiodes 14, 16, and 18, as shown schematically by the arrow. Nevertheless, based on the intensity at photodiodes 14, 16, and 18, detection of the respective emission intensity of the specifically assigned light-emitting diode 22, 24, and 26 can be determined.

Based on the evaluation of the signal level occurring at photodiodes 14, 16, and 18 due to the lighting by light-emitting diodes 22, 24, and 26, the various light-emitting diodes 22, 24, and 26 can be controlled in such a way that they emit a light ray composed of several components with a desired color composition predefinable by the control unit.

Because the wavelength selectivity of single layers 32, 34, 36 is limited due to production tolerances, the signals of photodiodes 14, 16, 18 can be compensated. To this end, the control unit in an embodiment of the invention that is not shown has a mathematical processing [function], e.g., an analog or digital addition or subtraction circuit, i.e., an adapted matrix circuit that can be realized as an operational amplifier. Thereby, based on a signal level of a first photodiode, which is sensitive only for a narrow-band first wavelength range, a signal level of a second photodiode whose coating has a lower discrimination and is therefore broadband, can be corrected. This occurs by linking the signal level of the first photodiode to the signal level of the second photodiode, so that the corresponding unwanted wavelength portion in the signal level of the second photodiode is eliminated.

In the graph according to FIG. 4, the layer thickness [nm] of the silicon nitride layer is plotted on the horizontal axis, whereas the signal level [A/W] of a photodiode standardized to an optical irradiance is plotted on the vertical axis; this is also called “sensitivity” or “responsivity.” The progressive curve shown with the circular measuring points was determined at a light wavelength of 785 nm. The progressive curve shown with the square measuring points was determined at a light wavelength of 658 nm. It is evident from FIG. 4 that a combination of the transmission of the silicon nitride coating at a layer thickness of about 275 nm with a wavelength-specific, physically determined signal response of the photodiode is identical for both light wavelengths, so that a photodiode coated in such a way enables an identical current flow at both wavelengths.

In the graph according to FIG. 5, the wavelength [nm] of the incident light is plotted on the horizontal axis, whereas the signal level of a photodiode standardized to an optical irradiance is plotted on the vertical axis [A/W] (responsivity=diode current relative to optical power). It is evident from FIG. 5 that for different layer thicknesses of the silicon nitride coating clearly different signal responses in the form of different electrical currents can be determined by the photodiode, so that a tuning of the photodiode to a predefinable wavelength can be achieved by adjusting the layer thickness.

This type of semiconductor component can be fabricated in existing production facilities for semiconductor components, because no additional coating processes or coating media are used. A compact, light-intensity-compensated lighting unit, particularly for lighting matrix screens, can be created by an integrated design of one or more light detectors and a control unit and optionally one or more light-emitting diodes.

In an embodiment of the invention not described in greater detail, the semiconductor component is realized on a gallium-arsenic substrate (GaAs). In this way, for example, a wavelength multiplexer could be produced in which three exemplary wavelengths (850 nm, 1310 nm, 1550 nm) are selectively conducted to three photodiodes, each of which enables further processing of the wavelength-specific signals, by means of a filter coating of the invention.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor component comprising an integrated circuit, which has at least one light detector having a silicon-containing coating or a coating of silicon nitride or silicon dioxide, a layer thickness of the silicon-containing coating being selected such that a predefinable, narrow-band wavelength-selective transmission of light waves is achieved, the light waves having a wavelength range from 400 nm to 850 nm.

2. The semiconductor component according to claim 1, wherein the silicon-containing coating is made as a homogeneous single-component layer having a layer thickness in the range between 50 nm and 4000 nm, with a layer thickness that corresponds to an integer multiple of a fourth of the wavelength of the light waves to be transmitted.

3. The semiconductor component according to claim 2, wherein the layer thickness of the silicon-containing coating or the coating of silicon nitride is selected in such a way that an inhomogeneous reception characteristic of the light detector is compensated at least partially for different light wavelengths.

4. The semiconductor component according to claim 3, wherein the layer thickness of the silicon-containing coating or the coating of silicon nitride is selected such that a high sensitivity of the light detector for a first wavelength by a low transmission of the coating for the first wavelength is adapted to a low sensitivity of the light detector for a second wavelength at a high transmission of the coating for the second wavelength.

5. The semiconductor component according to claim 1, further comprising at least two light detectors having silicon-containing coatings with a different layer thickness for detecting different light wavelengths, and are provided in the integrated circuit.

6. The semiconductor component according to claim 5, wherein the light detectors are formed as photodiodes.

7. The semiconductor component according to claim 1, wherein the integrated circuit is set up for detecting an emission spectrum of a light source arrangement made of a plurality of light sources or light-emitting diodes, which emit light in different wavelength ranges.

8. The semiconductor component according to claim 1, further comprising a control unit for processing the light detector signals.

9. The semiconductor component according to claim 8, wherein the control unit is formed to control light sources based on signals of the light detectors.

10. The semiconductor component according to claim 5, wherein the at least two light detectors have different layer thicknesses of the silicon-containing coating so that they have different sensitivities for incident light waves of different wavelengths.

11. The semiconductor component according to claim 9, wherein the control unit is formed for compensating signals of a light detector with broadband wavelength selection based on signals of at least one light detector with narrow-band wavelength selection.

12. A lighting unit for screens, particularly for matrix screens, having at least one semiconductor component according to claim 1 and having at least a light-source arrangement formed of a plurality of light sources or light-emitting diodes.

13. A method for the production of an integrated circuit, the method comprising:
applying a silicon-containing coating or a silicon nitride layer or a silicon dioxide layer, with a first layer thickness to a group of light detectors;
selectively applying a silicon-containing coating or a silicon nitride layer or a silicon dioxide layer, with a second layer thickness to a subgroup of the group of light detectors.

14. The method according to claim 13, wherein a silicon-containing coating or a silicon nitride layer or a silicon dioxide layer, with a third layer thickness is applied to a partial group of the subgroup of light detectors.
